(19) United States
(12) Patent Application Publication
(10) Pub. No.: US 2023/0257649 A1
(43) Pub. Date: Aug. 17, 2023

(54) PHOSPHOR AND LIGHT SOURCE DEVICE

(71) Applicant: TDK CORPORATION, Tokyo (JP)

(72) Inventors: Moeko KAKUDO, Tokyo (JP); Tatsuya TERUI, Tokyo (JP)

(73) Assignee: TDK CORPORATION, Tokyo (JP)

(21) Appl. No.: 17/898,895

(22) Filed: Aug. 30, 2022

(30) Foreign Application Priority Data
Feb. 15, 2022 (JP) 2022-021528

(51) Int. Cl. C09K 11/77; C30B 33/00

(52) U.S. Cl. CPC C09K 11/7721; C30B 33/00

(57) ABSTRACT

Provided is a phosphor in which a first phase and a second phase are three-dimensionally entangled with each other. The phosphor further includes a third phase different from the first phase and the second phase, in a cross-sectional visual field in a predetermined range, an area ratio of the third phase in the phosphor is 0.5% to 3.0%, and at least a part of the third phase is a bridging third phase existing at a position where a part of the first phase and another part of the first phase are bridged.

### BACKGROUND OF THE INVENTION

### 1. Field of the Invention

The present invention relates to a phosphor and a light source device that uses the phosphor.

### 2. Description of the Related Art

As one of methods for producing white light, there is a method in which a blue LED is applied to a yellow phosphor and blue light and yellow light that is emitted are mixed with each other. Typical examples of the yellow phosphor include a polycrystal, a single crystal, and a eutectic substance.

A eutectic phosphor typically includes an Al₂O₃ phase and a Ce:YAG phase. The eutectic phosphor has a structure in which two phases are complicatedly entangled, and thus strength is higher in comparison to a polycrystal phosphor. In addition, since the Al₂O₃ phase exists, heat conductivity is high as a whole, and as a result, there is an advantage in that thermal quenching is improved.

Note that, the thermal quenching is a phenomenon in which the phosphor has heat by excitation light, and fluorescent characteristics deteriorate.

On the other hand, in the eutectic substance, a ratio of a fluorescent component (Ce:YAG) in the entirety of a material is low, and thus there is a problem that the amount of fluorescence is small.

### SUMMARY OF THE INVENTION

The present invention has been made in consideration of the problem, and an object thereof is to provide a phosphor capable of improving light-emission efficiency while maintaining high thermal-quenching resistant characteristics.

To accomplish the object, according to an aspect of the present invention, there is provided a phosphor comprising a first phase and a second phase entangled three-dimensionally with each other.

the phosphor further comprises a third phase different from the first phase and the second phase,

an area ratio of the third phase in the phosphor is 0.5% to 3.0% in a predetermined range of a cross-section of the visual field, and

third phase includes a bridging third phase existing at a position where a part of the first phase and another part of the first phase are bridged.

According to the phosphor according to the present invention, light emission efficiency can be improved while maintaining high thermal quenching resistant characteristics. As the reason for this, the following point is considered. First, in the present invention, since the third phase exists in the phosphor in a predetermined area ratio, the third phase becomes a scattering factor, and the light emission efficiency can be enhanced. In addition, heat conductivity of the third phase according to the present invention is low, but heat conductivity of the first phase is high. Accordingly, when the bridging third phase exists at a position where a part of the first phase and another part of the first phase are bridged, heat of the third phase can be radiated through the first phase. According to this, heat accumulation in the third phase can be prevented, and the thermal quenching can be suppressed.

In addition, when the area ratio of the third phase is 0.5% or greater, a scattering effect due to the third phase is sufficiently exhibited, and the light emission efficiency is improved. On the other hand, when the area ratio of the third phase is 3.0% or less, the second phase can be sufficiently secured, and the light emission efficiency can be improved.

Preferably, the area ratio of the bridging third phase in the phosphor is 0.25% to 3.0% in a predetermined range of the cross-section of the phosphor.

When the area ratio of the bridging third phase is 0.25% or greater, heat accumulation in the third phase can be prevented, and the thermal quenching can be further suppressed.

Preferably, the third phase contains at least an activation element, and

the activation element is contained in the third phase preferably in an amount of 40 parts by mol or more,

when a total amount of elements contained in the third phase other than oxygen is set to 100 parts by mol.

According to this, the light emission efficiency can be enhanced.

Preferably, the activation element is Ce.

Since Ce has a high refractive index, when a predetermined amount of Ce is contained in the third phase, a scattering probability is improved, and thus the light emission efficiency is improved.

Preferably, the second phase comprises a fluorescence exhibiting phase.

Preferably, the second phase comprises a Ce:YAG phase.

Preferably, the first phase comprises an Al₂O₃ phase.

Preferably, the phosphor is produced by a micro pull-down method.

According to another aspect of the present invention, there is provided a light source device comprising the phosphor.

According to still another aspect of the present invention, there is provided a light source device comprising the phosphor and a blue light-emitting diode and/or a blue semiconductor laser.

### BRIEF DESCRIPTION OF THE DRAWINGS

FIG. 1 is a schematic perspective view of a phosphor according to an embodiment of the present invention;

FIG. 2 is a cross-sectional view of the phosphor which is taken along line II-II shown in FIG. 1;

FIG. 3 is an enlarged view of a portion III illustrated in FIG. 2;

FIG. 4 is an enlarged view of a portion IV illustrated in FIG. 3;

FIG. 5 is an enlarged view of a portion V illustrated in FIG. 3;

FIG. 6 is a schematic cross-sectional view of a crystal producing device that produces the phosphor according to the embodiment of the present invention;

FIG. 7 is an enlarged cross-sectional view of a portion VII of the crystal producing device illustrated in FIG. 6; and

FIG. 8 is an arrow view along line VIII-VIII of a die part illustrated in FIG. 7.

### DETAILED DESCRIPTION OF THE PREFERRED EMBODIMENTS

<Light Source Device>

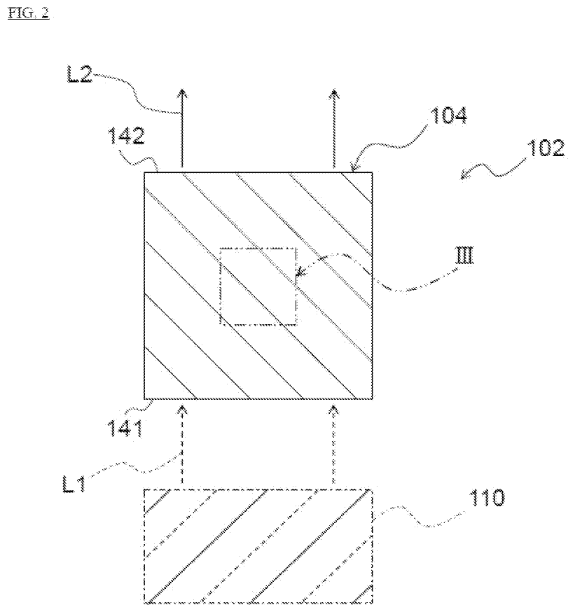

A light source device 102 according to an embodiment is illustrated in FIG. 2.

The light source device 102 according to this embodiment includes at least a phosphor 104 according to this embodiment, and a blue light-emitting element 110. As illustrated in FIG. 2, in this embodiment, a void is provided between the phosphor 104 and the blue light-emitting element 110.

<Blue Light-Emitting Element>

As illustrated in FIG. 2, the blue light-emitting element 110 emits blue light L1 that is excitation light for exciting a fluorescent component of the phosphor 104. In the blue light L1 of the blue light-emitting element 110, a peak wavelength is typically 425 to 475 nm. A part of the blue light L1 incident to a first plane 141 of the phosphor 104 is absorbed to the phosphor 104 and is frequency-converted, and emits fluorescence. In this manner, the generated fluorescence and the blue light L1 are mixed with each other, and white light L2 is emitted from a second plane 142 of the phosphor 104.

As the blue light-emitting element 110, there is no particular limitation as long as the blue light-emitting element 110 emits the white light L2 through mixing with the fluorescence, and can emit the blue light L1 capable of being wavelength-converted into the fluorescence by the phosphor 104, and examples thereof include a blue light-emitting diode (blue LED) or a blue semiconductor laser (blue LD).

<Phosphor>

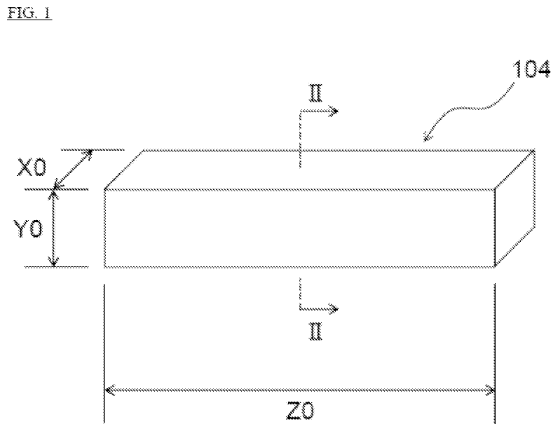

FIG. 1 illustrates the phosphor 104 according to this embodiment. The phosphor 104 illustrated in FIG. 1 has a rectangular parallelepiped columnar shape.

A size of the phosphor 104 according to this embodiment is not particularly limited, but “a length X0 in a vertical direction orthogonal to an optical path of the blue light L1 that is transmitted through the phosphor 104” is preferably a diameter equal to or greater than a spot diameter of incident light. According to this, a damage of the phosphor 104 due to a stress that occurs by local heating can be prevented.

“A length Y0 parallel to the optical path of the blue light L1 that is transmitted through the phosphor 104” is preferably 50 to 1000 μm. According to this, the blue light L1 can be allowed to sufficiently remain within the phosphor 104, and thus more satisfactory fluorescent characteristics can be obtained.

“A length in a lateral direction Z0 orthogonal to the optical path of the blue light L1 that is transmitted through the phosphor 104”, that is, a longitudinal direction Z0 is 100 μm or greater. According to this, the excitation light (the blue light L1) can be efficiently absorbed.

FIG. 2 illustrates a cross-section of the phosphor 104 which is taken along line II-II in FIG. 1. That is, the cross-section of the phosphor 104 in FIG. 2 is an arbitrary cross-section orthogonal to the longitudinal direction Z0.

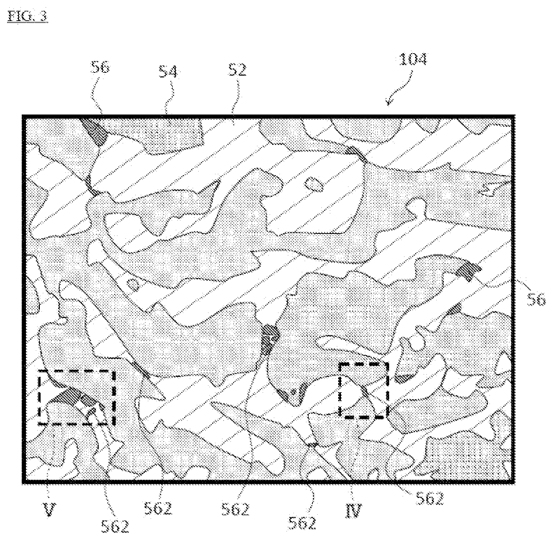

FIG. 3 is an enlarged view of a portion III in FIG. 2. As illustrated in FIG. 3, the phosphor 104 according to this embodiment includes a first phase 52, a second phase 54, and a third phase 56.

A component that constitutes the first phase 52 is not particularly limited, but the component is preferably an oxide of at least one or more selected among Al, Ba, Be, Ca, Co, Cr, Fe, Ga, Hf, Li, Mg, Mn, Nb, Ni, Si, Sn, Sr, Ta, Th, U, Y, Zn, Zr, and rare-earth elements (La, Ce, Pr, Nd, Sm, Eu, Gd, Tb, Dy, Ho, Er, Tm, Yb, and Lu), more preferably an oxide of at least one or more selected from Al, Ca, Si, and Zr, and still more preferably an oxide of Al.

It is preferable that heat conductivity of the first phase 52 is relatively high. According to this, the first phase 52 can mainly contribute an improvement of the thermal-quenching resistant characteristics of the phosphor 104.

It is preferable that the second phase 54 in this embodiment is a fluorescence expressing phase that mainly expresses fluorescence.

A component that constitutes the second phase 54 is not particularly limited, but it is preferable that an oxide of at least one or more selected among Al, Ba, Be, Ca, Co, Cr, Fe, Ga, Hf, Li, Mg, Mn, Nb, Ni, Si, Sn, Sr, Ta, Th, U, Y, Zn, Zr, and rare-earth elements (La, Ce, Pr, Nd, Sm, Eu, Gd, Tb, Dy, Ho, Er, Tm, Yb, and Lu), more preferably an oxide of at least one or more selected along Al, Lu, Y, and Si, and still more preferably an oxide of at least one or more selected among Al, Lu, and Y is activated by an activation element, and the fluorescent characteristics are imparted.

Note that, the activation element is not particularly limited, and examples thereof include at least one selected from the group consisting of Ce, Pr, Sm, Eu, Tb, Dy, Tm, and Yb. According to this, the light emission characteristics can be imparted. From the above-described viewpoint, the activation element is preferably Ce or Eu, and more preferably Ce.

The second phase 54 can also be expressed as follows. The second phase 54 includes an element α including at least any one of Y and Lu and an element β that is an additive, and is expressed by (α₁₋ₓβₓ)₃₊ₐAl₅₋ₐO₁₂(0.0001≤x≤0.007, −0.016≤a≤0.315).

Here, as the element α, Gd, Tb, or La may be contained other than the above-described elements. In addition, the element α preferably includes at least Y. When the element α includes at least Y, the light emission characteristics can be improved. The element β that is an additive is the above-described activation element.

A component that constitutes the third phase is not particularly limited, but the same component as the component that constitutes the second phase 54 can be contained. However, a concentration of the activation element is different between the third phase 56 and the second phase 54, and it is preferable that the concentration of the activation element in the third phase 56 is higher than the concentration of the activation element in the second phase 54. Specifically, when a total amount of elements contained in the third phase 56 other than oxygen is set to 100 parts by mol, it is preferable that the third phase 56 contains the activation element in an amount of 40 parts by mol or more, and more preferably 50 to 75 parts by mol.

In addition, the activation element contained in the third phase 56 can improve scattering probability due to a high refractive index. According to this, light emission efficiency is further improved. From this viewpoint, the activation element contained in the third phase 56 is preferably Ce.

The third phase 56 may be crystalline or amorphous.

Note that, a concentration of each component in the phosphor 104 can be measured by laser ablation ICP mass analysis (LA-ICP-MS), an electron probe analyzer (EPMA), an energy dispersive spectrometer (EDX), or the like. In a case where component analysis is performed by the EPMA, an energy dispersive spectrometer (EDS) or a wavelength dispersive spectrometer (WDS) can be used as an X-ray spectrometer.

As illustrated in FIG. 3, in the phosphor 104 according to this embodiment, a state in which the first phase 52 and the second phase 54 are entangled is observed in a cross-sectional visual field in a predetermined range. Note that, since FIG. 3 is a cross-sectional view of the phosphor 104, only a two-dimensionally entangled state is illustrated, but actually, the first phase 52 and the second phase 54 has a three-dimensionally entangled structure.

As illustrated in FIG. 3, the phosphor 104 according to this embodiment contains a small amount of third phase 56.

In this embodiment, in the cross-sectional visual field in a predetermined range, an area ratio of the third phase 56 in the phosphor 104 is 0.5% to 3.0%, and preferably 1.50% to 1.55%.

Note that, the “cross-sectional visual field in a predetermined range” is preferably a visual field of (50 to 100 μm)×(50 to 100 μm), and more preferably a visual field of (50 to 80 μm)×(50 to 80 μm).

The third phase 56 according to this embodiment may include the first phase 52 at a part thereof. In addition, in a case where the third phase 56 includes a fine first phase 52 having an equivalent circle diameter of 1 μm or less, an area ratio of the third phase 56 and a bridging third phase 562 to be described later is measured while ignoring the fine first phase 52. That is, the fine first phase 52 is also measured as a part of the third phase 56 or the bridging third phase 562.

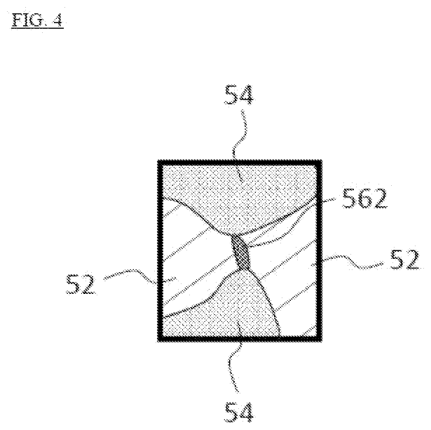

In this embodiment, at least a part of the third phase 56 is the bridging third phase 562. As illustrated in FIG. 4 that is an enlarged view of a portion IV in FIG. 3, the bridging third phase 562 exists at a position that bridges a part of the first phase 52 and another part of the first phase 52.

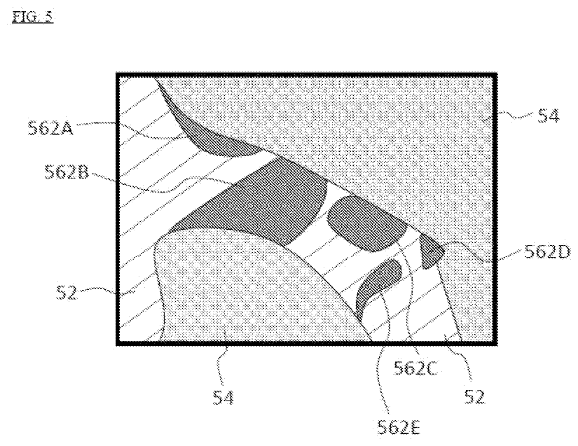

FIG. 5 is an enlarged view of a portion V in FIG. 3. It seems that bridging third phases 562A, and 562C to 562E in FIG. 5 do not exist alone at a position that bridges a part of the first phase 52 and another part of the first phase 52, but since an adjacent bridging third phase 562B, and the bridging third phases 562A, and 562C to 562E exist in an aggregated state, not only the third bridging phase 562B but also the bridging third phases 562A, and 562C to 562E locate at a position that bridges a part of the first phase 52 and another part of the first phase 52. That is, the bridging third phase 562 may not be continue from a part of the first phase 52 to another part of the first phase 52. A distance between the bridging third phase 562 that constitutes the bridging third phase 562 due to aggregation, and another bridging third phase 562 is preferably 1 μm or less. Accordingly, an area ratio of the bridging third phase 562 to be described later is obtained in a state in which the bridging third phases 562A, and 562C to 562E in FIG. 5 are also set as a part of the bridging third phase 562.

In this embodiment, in the cross-sectional visual field in a predetermined range, the area ratio of the bridging third phase 562 in the phosphor 104 is preferably 0.25% to 3.0%, and more preferably 1.50% to 3.00%.

A structure of the cross-section of the phosphor 104 can be analyzed through observation with a scanning electron microscope (SEM), a scanning transmission electron microscope (STEM), or the like. Specifically, in a backscattered electron image of the SEM, an HAADF image of the STEM, as a density is higher, the image is captured with a bright contrast. Accordingly, the third phase 56 can be recognized as a portion with the brightest contrast, the second phase 54 can be recognized is a bright portion next to third phase 56, and the first phase 52 can be recognized as a darkest portion, and thus shapes and areas of the third phase 56, the second phase 54, and the first phase 52 can be confirmed.

<Method of Producing Phosphor>

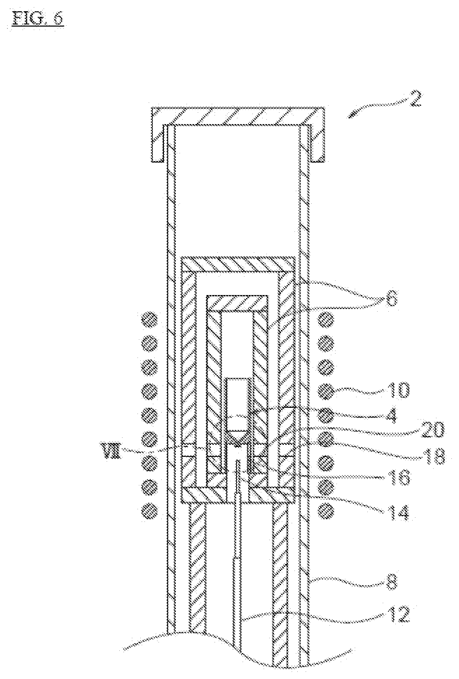

The phosphor 104 according to this embodiment can be produced by a p-PD method (micro pull-down method). A crystal producing device 2 of this embodiment is illustrated in FIG. 6. The p-PD method is a melt solidification method in which a crucible 4 into which a sample is put is directly or indirectly heated to obtain a melt of a target material in the crucible 4, a seed crystal 14 provided on a downward side of the crucible 4 is brought into contact with an opening of a lower end of the crucible 4, and the seed crystal 14 is pulled down while forming a solid-liquid interface at the opening to grow a crystal.

The crystal producing device 2 of this embodiment includes the crucible 4 and a refractory furnace 6. The refractory furnace 6 doubly covers the periphery of the crucible 4. An observation window 20 for observing a pull-down state of the melt from the crucible 4 is provided in the refractory furnace 6.

The refractory furnace 6 is further covered with an outer casing 8, and a main heater 10 that heats the entirety of the crucible 4 is provided at an outer periphery of the outer casing 8. In this embodiment, for example, the outer casing 8 is formed from a quartz tube, and as the main heater 10, an induction heating coil (a high-frequency coil for heating) 10 is used.

The seed crystal 14 held to a seed crystal support jig 12 is disposed on a downward side of the crucible 4. Although not be particularly limited, as the seed crystal 14, a crystal that is the same or the same kind of crystal as a crystal to be produced can be used. For example, when the crystal to be produced is a eutectic of an aluminum oxide and Ce-doped YAG, as the seed crystal 14, a YAG single crystal, sapphire, or the like is used.

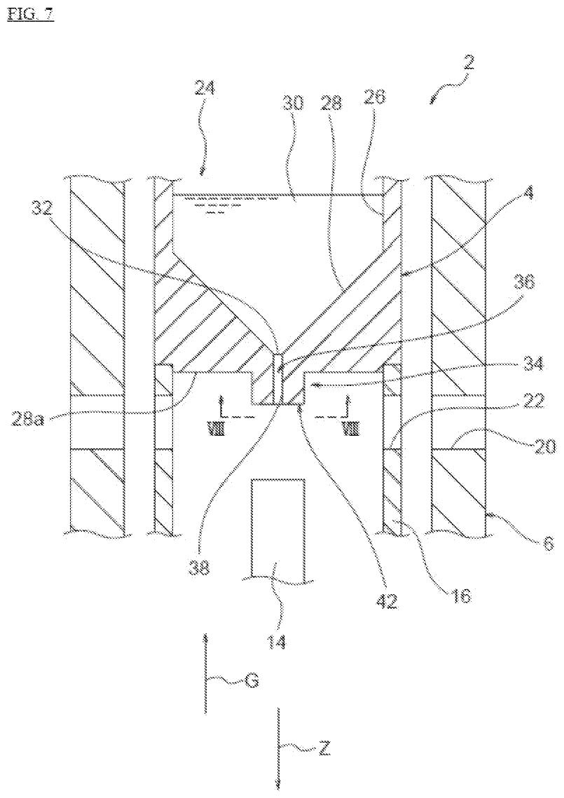

As illustrated in FIG. 6 and FIG. 7, a tubular after-heater 16 is provided at the outer periphery of a lower end of the crucible 4. In the after-heater 16, an observation window 22 is formed at the same position as in the observation window 20 of the refractory furnace 6. The after-heater 16 is used in a state of being connected to the crucible 4, is disposed so that a die outflow port 38 of a die part 34 of the crucible 4 is located in an inner space of the tubular after-heater 16, and is configured to heat the die part 34 and a melt that is taken out from the die outflow port 38. For example, the after-heater 16 is formed from the same material as that of the crucible 4 (may not be the same), or the like, the after-heater 16 is inductively heated by the main heater 10 similarly to the crucible 4, radiant heat is generated from an outer surface of the after-heater 16, and the inside of the after-heater 16 can be heated.

Note that, although not illustrated, the crystal producing device 2 is provided with a depressurizing unit that reduces the pressure inside the refractory furnace 6, a pressure measurement unit that monitors a reduction in pressure, a temperature measurement unit that measures a temperature of the refractory furnace 6, and a gas supply unit that supplies an inert gas G to the inside of the refractory furnace 6.

The material of the crucible 4 is preferably Ir, Re, Mo, Ta, W, Pt, or an alloy thereof from the viewpoint that a melting point of a crystal is high. In addition, the crucible 4 may be formed from carbon (C). In addition, it is more preferable that Ir is used as the material of the crucible 4 to prevent mixing of foreign matters into a crystal due to oxidation of the material of the crucible 4.

Note that, in a case where a material having a melting point of 1500° C. or lower is set as a target, Pt can be used as the material of the crucible 4. In addition, in a case of using Pt as the material of the crucible 4, crystal growth in the air is possible. In a case where a material having a high melting point higher than 1500° C. is set as a target, since Ir or the like is used as the material of the crucible 4, the crystal growth is preferably performed under an inert gas atmosphere such as Ar. The material of the refractory furnace 6 is not particularly limited, but alumina is preferable from the viewpoints of a heat retention property, a use temperature, and prevention of mixing of impurities into a crystal.

Next, description will be given of the crucible 4 that is used in the crystal producing device 2 of this embodiment. As illustrated in FIG. 7, the crucible 4 according to this embodiment includes a melt storage part 24 that stores a melt 30 that becomes a raw material of a crystal, and the die part 34 that controls a shape of the crystal, and the parts are integrally formed. Note that, in a case where the crucible 4 has a large size, the crucible 4 may be constituted by joining a plurality of members in the middle of a longitudinal direction of the melt storage part 24.

In this embodiment, the crucible 4 is used in the p-PD method, the die part 34 is located on a lower side of the melt storage part 24 in a vertical direction, and the melt 30 stored in the melt storage part 24 is taken out from the die outflow port 38 formed in a lower end surface 42 of the die part 34 to a lower side in the vertical direction Z by the seed crystal 14.

The melt storage part 24 is constituted by a side wall 26 having a tubular shape, and a bottom wall 28 that is formed continuously to the side wall 26. An inner surface of the side wall 26 and an inner surface of the bottom wall 28 are configured so that a constant amount of melt 30 can be stored in the melt storage part 24. A storage part outlet port 32 is formed at approximately the central portion of the bottom wall 28. The storage part outlet port 32 communicates with a die flow passage 36 that is formed in the die part 34. The die flow passage 36 will be described later.

The inner surface of the bottom wall 28 is an inclined surface having a reverse tapered shape in which an inner diameter decreases as going toward a lower side, and thus the melt 30 inside the melt storage part 24 easily flows toward the storage part outlet port 32. An outer surface of the bottom wall 28 is preferably flushed with an outer surface of the side wall 26, and is also flushed with an outer surface of the after-heater 16. A lower surface 28a of the bottom wall 28 is a flat surface that is approximately orthogonal to a flow direction of the melt 30 (also referred to as a drawing direction or a pull-down direction) Z, and the after-heater 16 is connected to the outer peripheral portion of the lower surface 28a.

In an approximately central portion of the lower surface 28a of the bottom wall 28, at least a part of the die part 34 is formed to protrude to a downward side. Specifically, a lower end surface 42 of the die part 34 protrudes from the lower surface 28a of the bottom wall 28 by a predetermined distance. The die outflow port 38 formed in the approximately central portion of the lower end surface 42 of the die part 34, and the storage part outlet port 32 formed in the approximately central portion of the bottom wall 28 are connected to each other by the die flow passage 36 formed in the die part 34.

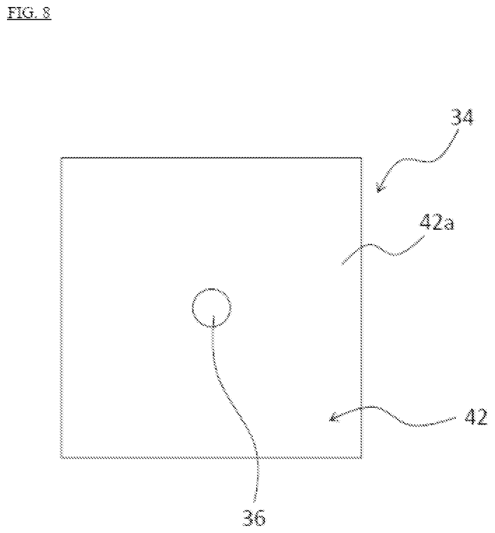

As illustrated in FIG. 8, in the lower end surface 42 of the die part 34, a flat end peripheral surface 42a that is substantially orthogonal to the drawing direction Z is formed at the periphery of the die outflow port 38. The end peripheral surface 42a is formed between an outer shape of the lower end surface 42 of the die part 34 and an outer shape of the die outflow port 38.

A shape of a lateral cross-section (a cross-section orthogonal to the pull-down direction Z) of the phosphor 104 that is obtained is formed in conformity to the lower end surface 42 of the die part 34. That is, when the outer shape of the lower end surface 42 of the die part 34 is a rectangular shape, a shape of a lateral cross-section of the obtained phosphor 104 also becomes a rectangular shape.

In this embodiment, the outer shape of the lower end surface 42 of the die part 34 is a rectangular shape conforming to the shape of the lateral cross-section (cross-section orthogonal to the pull-down direction Z) of the obtained phosphor 104, and the shape of the die outflow port 38 is a circular shape, but there is no limitation thereto. For example, the outer shape of the lower end surface 42 of the die part 34 can also be set to a circular shape, a polygonal shape, an elliptical shape, or other shapes in conformity to the cross-sectional shape of the obtained phosphor 104, and the cross-sectional shape of the die outflow port 38 is not limited to the circular shape and can also be set to a polygonal shape, an elliptical shape, or other shapes. In addition, the cross-sectional shape of the die flow passage 36 is not limited to the circular shape and can also be set to a polygonal shape, an elliptical shape, or other shapes.

Next, description will be given of a method for producing the phosphor 104 by using the crystal producing device 2 of this embodiment. In the crystal producing device 2 of this embodiment, first, the inside of the furnace is substituted with an inert gas G. The kind of the inert gas G is not particularly limited, but it is preferable to prevent oxidation of the phosphor 104, and examples thereof include nitrogen, argon, hydrogen, and the like.

Next, the crucible 4 is heated by the main heater 10 while causing the inert gas G to flow in at a flow rate of 10 to 100 ml/min, and a raw material is melted to obtain a melt. A raw material of a phosphor to be obtained is put into the melt storage part 24 of the crucible 4, and the main heater 10 is activated to heat the melt storage part 24. When the melt storage part 24 is heated, the raw material is melted at the inside of the melt storage part 24, becomes the melt 30, and flows from the storage part outlet port 32 of the die part 34 to the die flow passage 36. The melt 30 comes into contact with an upper end of the seed crystal 14 at the die outflow port 38.

Before and after the heating, the after-heater 16 is also activated to heat the vicinity of the die part 34.

When the raw material is sufficiently melted, the melt exudes from the die outflow port 38 at the lower end of the crucible 4, and spreads out on the lower end surface 42 of the die part 34. On the other hand, the seed crystal 14 is gradually brought closer from the lower portion of the crucible 4 and the seed crystal 14 is brought into contact with the vicinity of the die outflow port 38 at the lower end of the crucible 4, and the seed crystal 14 is pulled down to initiate crystal growth.

A crystal growth rate is manually controlled in combination with a temperature while observing a state of a solid-liquid interface with a CCD camera or a thermo-camera.

The crystal growth rate can be selected by movement of the main heater 10.

The seed crystal 14 is pulled down until the melt inside the crucible 4 does not flow out, and the seed crystal 14 is detached from the crucible 4.

During the crystal growth, the inside of the refractory furnace 6 is maintained in a state in which the inert gas G is introduced under the same condition as in heating.

In this embodiment, the pull-down direction (crystal growth direction) Z of the seed crystal 14 may match or may not match the horizontal direction (longitudinal direction, Z0 direction) of the phosphor 104, but it is preferable that the pull-down direction Z of the seed crystal 14 matches the horizontal direction of the phosphor 104. In other words, the pull-down direction Z of the seed crystal 14 may match or may not match a vertical direction of the optical path of the blue light L1 that is transmitted through the phosphor 104, but it is preferable that the pull-down direction Z of the seed crystal 14 matches the vertical direction of the optical path of the blue light L1 that is transmitted through the phosphor 104.

In the phosphor 104 according to this embodiment, the first phase 52 and the second phase 54 that exhibits the fluorescent characteristics are three-dimensionally entangled, and the phosphor 104 further includes a predetermined third phase 56. A method of producing the phosphor 104 is not particularly limited, and examples thereof include “a method in which a concentration of an injected activation element is set within a predetermined range”, “a method in which a phosphor growing rate is set to be slow”, “a method in which the phosphor growing rate is set to be considerably fast”, and a combination thereof.

First, description will be given of “a method in which a concentration of an injected activation element is set within a predetermined range”. For example, when a total amount of elements contained in the phosphor 104 other than oxygen is set to 100 parts by mol, the concentration of the injected activation element is controlled so that the activation element is contained in the phosphor 104 preferably in an amount of 0.30 to 1.50 parts by mol, and more preferably in an amount of 0.65 to 1.10 parts by mol. In this manner, when the concentration of the injected activation element is set to be relatively high, a large amount of third phase 56 that cannot be contained in a eutectic phase of the first phase 52 and the second phase 54 can precipitate.

Description will be given of “a method in which a phosphor growing rate is set to be slow”. For example, the phosphor growing rate is preferably controlled to 0.01 to 0.50 mm/min, and more preferably 0.30 to 0.50 mm/min. When the phosphor growing rate is set to be relatively slow, a large amount of third phase 56 that cannot be contained in the eutectic phase of the first phase 52 and the second phase 54 can precipitate. The reason for this is because when the phosphor growing rate is slow, growth can be performed while sufficiently excluding the third phase 56 that is a hetero phase. Note that, the phosphor growing rate can be selected by movement of the main heater 10.

Description will be given of “a method in which a phosphor growing rate is set to be considerably fast”. For example, the phosphor growing rate is preferably controlled to 7.00 to 10.00 mm/min. Since the phosphor is grown considerably fast, precipitation of a large amount of third phase 56 that precipitates to an interface of the first phase 52 occurs. The third phase 56 that precipitates to the interface of the first phase 52 is likely to bridge the first phase 52 and the first phase 52, and thus the bridging third phase 562 is likely to be formed.

In the ρ-PD method, an adjustment width of the phosphor growing rate is wider in comparison to a CZ (Czochralski Method) in the related art, and thus the third phase 56 and the bridging third phase 562 are likely to be obtained. Accordingly, it is preferable that the phosphor 104 according to this embodiment is produced by the μ-PD method.

According to the phosphor 104 according to this embodiment, the light emission efficiency can be improved while suppressing the thermal quenching. As the reason for this, the following point is considered. First, in the phosphor 104 according to this embodiment, since the first phase 52 and the second phase 54 have the complicatedly entangled structure, scattering is likely to occur, and thus the light emission efficiency is high and a color mixture property between the blue light (excitation light) L1 and the fluorescence is satisfactory.

Note that, the color mixture property is expressed by a standard deviation of CIEν value when a predetermined range of a crystal is beam-analyzed, and as the standard deviation of the CIEν value is low, it is determined that color mixture property is satisfactory.

In addition, in this embodiment, since the third phase 56 exists in the phosphor 104 in a predetermined area ratio, the third phase 56 becomes a scattering factor, and the light emission efficiency and the color mixture property can be enhanced.

In addition, the heat conductivity of the third phase 56 according to this embodiment is low, but the heat conductivity of the first phase 52 is high. Accordingly, when the bridging third phase 562 exists at a position where a part of the first phase 52 and another part of the first phase 52 are bridged, heat of the third phase 56 can be radiated through the first phase 52. According to this, heat accumulation in the third phase 56 can be prevented, and the thermal quenching can be suppressed.

In addition, when the area ratio of the third phase 56 is 0.5% or greater, a scattering effect due to the third phase 56 is sufficiently exhibited, and the light emission efficiency is improved. On the other hand, when the area ratio of the third phase 56 is 3.0% or less, the second phase 54 can be sufficiently secured, and the light emission efficiency can be improved.

Furthermore, in the phosphor 104 according to this embodiment, since the first phase 52 such as an Al₂O₃ phase exists, heat conductivity as a whole is high, and as a result thereof, there is an advantage that the thermal quenching is improved.

The present invention is not limited to the above-described embodiment, and various modifications can be made within the scope of the present invention.

For example, in the above-described embodiment, the cross-section of the phosphor 104 in FIG. 2 is an arbitrary cross-section orthogonal to the longitudinal direction Z0, but a direction of the cross-sectional visual field of the phosphor according to the present invention is not particularly limited, and may be a cross-section other than the cross-section orthogonal to Z0.

In addition, in the above description, a void is provided between the phosphor 104 and the blue light-emitting element 110, but the phosphor 104 and the blue light-emitting element 110 may be in close contact with each other. In addition, a transparent resin may be provided between the phosphor 104 and the blue light-emitting element 110.

In addition, in the method for producing the phosphor 104, growth can be performed by an EFG method in addition to the μ-PD method. Note that, description of the EFG method is as follows.

First, a raw material is put into a crucible and is heated to be melted. The melted raw material is guided to an opening of a slit die (die for crystal growth) that is provided in the crucible in an erected manner. In a state in which a seed crystal is brought into contact with the raw material melt in the opening, when the seed crystal is pulled up, the melt is sucked up by a capillary phenomenon and a crystal is grown. A cross-sectional shape of the crystal can be controlled by a size of the slit die.

### EXAMPLES

Hereinafter, the present invention will be described with reference to more detailed examples, but the present invention is not limited to the examples.

### Examples 1 to 10, and Comparative Examples 1, and 3 to 5

The phosphor 104 in which the first phase 52 is set to Al₂O₃, and the second phase 54 is set to Ce:YAG was produced by the μ-PD method by using the crystal producing device 2 illustrated in FIG. 6.

As starting raw materials, Y₂O₃, Al₂O₃, and CeO₂ were prepared, and the raw materials were put into an Ir crucible 4 having an inner diameter of 16 mm. With regard to a blending ratio of the starting raw materials, when a total amount of Y₂O₃, Al₂O₃, and CeO₂ was set to 100 parts by mol, Y₂O₃ was (20−z) parts by mol, Al₂O₃ was 80 parts by mol, and CeO₂ was z parts by mol. Values of z of respective samples are shown in Table 1.

Next, the crucible 4 into which the raw materials were put was placed in the refractory furnace 6, and an atmosphere of the refractory furnace 6 was substituted with N₂. An N₂ gas (inert gas G) was caused to flow into the refractory furnace 6 while maintaining the inside of the refractory furnace 6 to a normal pressure to perform crystal growth.

Then, heating of the crucible 4 was initiated, and heating was gradually performed for one hour until reaching a eutectic point of Ce:YAG and Al₂O₃, and then, the crucible 4 was further heated for one hour for convection and sufficient mixing.

A YAG single crystal was used as the seed crystal 14, the tip end of the seed crystal 14 was brought into contact with the die outflow port 38 in the lower end of the crucible 4, and after confirming that the melt flows out from the die outflow port 38, growth of the phosphor was initiated while lowering the seed crystal 14. A lowering rate of the seed crystal 14 was referred to as “growth rate”. At this time, crystal growth was performed by changing the growth rate for every sample as described in Table 1.

As a result, a columnar phosphor having a diameter of 10 mm and a length of 40 mm was obtained. Specifically, in Comparative Example 1, a eutectic substance of Ce:YAG phase and Al₂O₃ was obtained, and in Comparative Examples 3 to 5, and Examples 1 to 10, a phosphor including an Al₂O₃ phase (first phase), a Ce:YAG phase (second phase), and a third phase was obtained. Here, “length” a length Z0 in a longitudinal direction, and the longitudinal direction corresponds to the drawing direction Z.

In addition, in Comparative Example 1, Comparative Examples 3 to 5, and Examples 1 to 10, the Ce:YAG phase and the Al₂O₃ phase could be confirmed by an X-ray diffraction method (XRD) and SEM.

<Cross-Section Observation>

A cross-section was obtained so that the length Z0 in the longitudinal direction of the obtained phosphor becomes 1 mm. With respect to the obtained cross-section, “an area ratio of the third phase” was measured at a visual field of 55 μm×77 μm at ten sites. An average value thereof is shown in Table 1. In the same manner, with respect to the obtained cross-section, “an area ratio of the bridging third phase” was measured at a visual field of 55 μm×77 μm at ten sites. An average value thereof is shown in Table 1.

<Content of Ce in Third Phase>

The content of Ce was measured with respect to approximately the center of a site confirmed as the third phase by EPMA in the cross-section observation. Specifically, surface carbon was deposited onto a surface subjected to LA-ICP-MS measurement. Then, EPMA-SEM observation was performed by JXA-8500F type FE-EPMA (manufactured by JEOL LTD.). Observation conditions were as follows.

Acceleration voltage: 15 kV

Irradiation current: 0.1 μA

Spot diameter: 0.50 μm

Results are shown in Table 1. Note that, “Content of Ce in third phase” in Table 1 represents “the content of Ce of the third phase when a total amount of elements contained in the third phase other than oxygen is set to 100 parts by mol”, and more specifically, “Content of Ce in third phase” represents “the content of Ce of the third phase when a total amount of Y, Al, and Ce contained in the third phase is set to 100 parts by mol”.

<Light Emission Efficiency>

The obtained columnar eutectic phosphor was cut out in a size of X0×Y0×Z0=2.5 mm×2.5 mm×2.0 mm to obtain a measurement sample. With respect to the measurement sample, light emission efficiency was measured under the following conditions by using total light flux system FM Series (manufactured by Otsuka Electronics Co.,Ltd.).

Integrating sphere size: 1000 mm

Atmospheric temperature: 25° C.

Excitation wavelength: 450 nm

An irradiation area with excitation light was set to be sufficiently smaller with respect to a measurement sample surface. Results are shown in Table 1.

<150° C. Light Emission Intensity Retention Rate>

A 150° C. light emission intensity retention rate represents a ratio (thermal quenching resistant characteristics) of light emission efficiency of each sample at 150° C. to light emission efficiency of each sample at 25° C. Results are shown in Table 1. The 150° C. light emission intensity retention rate is preferably close to 100%.

A measurement method of an internal quantum yield rate which is used in calculation of the 150° C. light emission intensity retention rate was as follows. The obtained columnar eutectic phosphor was cut out in a size of X0×Y0×Z0=2.5 mm×2.5 mm×2.0 mm to obtain a measurement sample. With respect to the measurement sample, measurement was performed under the following conditions by using total light flux system FM Series (manufactured by Otsuka Electronics Co.,Ltd.) (manufactured by Hitachi High-Tech Corporation).

Integrating sphere size: 1000 mm

Excitation wavelength: 450 nm

Measurement temperature: 150° C.

An irradiation area with excitation light was set to be sufficiently smaller with respect to a measurement sample surface.

### Comparative Example 2

In Comparative Example 2, a Ce:YAG polycrystal was produced by the following method. Powders of Y₂O₃, Al₂O₃, and CeO₂ were mixed by using silicon ethyl silicate as a binder, and a disc-shaped green compact was obtained at a CIP pressure of 140 MPa. Note that, with regard to a composition of Comparative Example 2, when a total amount of Y₂O₃, Al₂O₃, and CeO₂ is set to 100 parts by mol, Y₂O₃ was (20−z) parts by mol, Al₂O₃ was 80 parts by mol, and CeO₂ was z parts by mol. Values of z in Comparative Example 2 are shown in Table 1. The obtained disc-shaped green compact was vacuum-sintered at a temperature of 1500° C. to 1600° C. to obtain a Ce:YAG polycrystal.

With respect to the obtained Ce:YAG polycrystal, “an area ratio of the third phase”, “the content of Ce in the third phase”, “an area ratio of the bridging third phase”, “light emission efficiency”, and “150° C. light emission intensity retention rate” were evaluated. Results are shown in Table 1.

TABLE 1

| | | | | | 150° C. light emission | | Content of Ce in |
|---|---|---|---|---|---|---|---|
| | | The content of | Light | Area ratio of | intensity retention rate | | fluorescent |
| | Area ratio of | Ce in third | emission | bridging third | (temperature quenching | | substance |
| | third phase | phase | efficiency | phase | resistant characteristics) | Growth rate | (z) |
| | [%] | [mol %] | [lm/W] | [%] | [%] | [mm/min] | [mo] %] |
| Comparative Example 1 | 0 | 0 | 235 | 0 | 85.0 | 1.00 | 0.05 |
| Comparative Example 2 | 0 | 0 | 435 | 0 | 65.0 | — | 0.40 |
| Comparative Example 3 | 3.05 | 40.1 | 239 | 0 | 77.0 | 0.01 | 1.50 |
| Comparative Example 4 | 0.40 | 40.1 | 239 | 0.31 | 83.5 | 0.50 | 0.70 |
| Example 1 | 0.53 | 40.4 | 250 | 0.45 | 83.2 | 0.30 | 0.70 |
| Example 2 | 1.52 | 40.0 | 270 | 0.81 | 82.0 | 0.10 | 0.70 |
| Example 3 | 3.00 | 40.2 | 251 | 1.43 | 81.8 | 0.07 | 0.70 |
| Comparative Example 5 | 3.15 | 40.2 | 240 | 1.47 | 81.2 | 0.05 | 0.70 |
| Example 4 | 1.52 | 38.6 | 266 | 0.83 | 82.1 | 0.10 | 0.65 |
| Example 2 | 1.52 | 40.0 | 270 | 0.81 | 82.0 | 0.10 | 0.70 |
| Example 5 | 1.54 | 50.5 | 277 | 0.78 | 81.8 | 0.10 | 1.10 |
| Example 6 | 1.55 | 70.1 | 279 | 0.80 | 81.9 | 0.10 | 1.50 |
| Example 7 | 1.54 | 40.1 | 245 | 0.24 | 80.0 | 0.03 | 0.30 |
| Example 8 | 1.55 | 40.1 | 250 | 0.25 | 80.5 | 0.01 | 0.30 |
| Example 2 | 1.52 | 40.0 | 270 | 0.81 | 82.0 | 0.10 | 0.70 |
| Example 9 | 1.51 | 40.3 | 273 | 1.50 | 83.3 | 7.00 | 0.70 |
| Example 10 | 3.00 | 40.3 | 257 | 3.00 | 85.0 | 10.00 | 1.50 |

From Table 1, it could be confirmed that in a case where the area ratio of the third phase in the phosphor is 0.5% to 3.0% (Examples 1 to 10), the light emission efficiency is higher in comparison to a eutectic substance (Comparative Example 1) that does not include the third phase.

From Table 1, it could be confirmed that in a case where the area ratio of the third phase in the phosphor is 0.5% to 3.0% (Examples 1 to 10), the 150° C. light emission intensity retention rate is higher in comparison to the polycrystal (Comparative Example 2) that does not include the third phase.

From Table 1, it could be confirmed that in a case where the area ratio of the third phase in the phosphor is 0.5% to 3.0%, and at least a part of the third phase is the bridging third phase (Examples 1 to 10), the light emission efficiency and the 150° C. light emission intensity retention rate are higher in comparison to a case where the area ratio of the third phase in the phosphor is 3.05%, and the bridging third phase is not included (Comparative Example 3).

From Table 1, it could be confirmed that in a case where the area ratio of the third phase in the phosphor is 0.5% to 3.0% (Examples 1 to 10), the light emission efficiency is higher in comparison to a case where the area ratio of the third phase in the phosphor is 0.40% (Comparative Example 4).

From Table 1, it could be confirmed that in a case where the area ratio of the third phase in the phosphor is 0.5% to 3.0% (Examples 1 to 10), the light emission efficiency is higher in comparison to a case where the area ratio of the third phase in the phosphor is 3.15% (Comparative Example 5).

From Table 1, it could be confirmed that in a case where an area ratio of the bridging third phase in the phosphor is 0.25% to 3.0% (Examples 1 to 6, and 8 to 10), the light emission efficiency is higher in comparison to a case where the area ratio of the bridging third phase in the phosphor is 0.24% (Example 7).

From Table 1, it could be confirmed that when comparing cases where the area ratio of the third phase in the phosphor is 1.52% (Examples 2 and 4), the light emission efficiency is higher in a case where 40 parts by mol or more of Ce is contained in the third phase (Example 2).

### EXPLANATIONS OF LETTERS OR NUMERALS

102 LIGHT SOURCE DEVICE
104 PHOSPHOR
   141 FIRST PLANE
   142 SECOND PLANE
110 BLUE LIGHT-EMITTING ELEMENT
2 CRYSTAL PRODUCING DEVICE
4 CRUCIBLE
6 REFRACTORY FURNACE
8 OUTER CASING
10 MAIN HEATER
12 SEED CRYSTAL SUPPORT JIG
14 SEED CRYSTAL
16 AFTER-HEATER
18, 20, 22 OBSERVATION WINDOW
24 MELT STORAGE PART
26 SIDE WALL
28 BOTTOM WALL
   28a LOWER SURFACE
30 MELT
32 STORAGE PART OUTLET PORT
34 DIE PART
36 DIE FLOW PASSAGE
38 DIE OUTFLOW PORT
42 END SURFACE
   42a END PERIPHERAL SURFACE
52 FIRST PHASE
54 SECOND PHASE
56 THIRD PHASE
   562, 562A to 562E BRIDGING THIRD PHASE
L1 BLUE LIGHT
L2 WHITE LIGHT

What is claimed is:

1. A phosphor comprising a first phase and a second phase entangled three-dimensionally with each other,
wherein the phosphor further comprises a third phase different from the first phase and the second phase,
an area ratio of the third phase in the phosphor is 0.5% to 3.0% in a predetermined range of a cross-section of the visual field, and
the third phase includes a bridging third phase existing at a position where a part of the first phase and another part of the first phase are bridged.

2. The phosphor according to claim 1,
wherein the area ratio of the bridging third phase in the phosphor is 0.25% to 3.0% in a predetermined range of the cross-section of the phosphor.

3. The phosphor according to claim 1,
wherein the third phase contains at least an activation element, and
the activation element is contained in the third phase in an amount of 40 parts by mol or more,
when a total amount of elements contained in the third phase other than oxygen is set to 100 parts by mol.

4. The phosphor according to claim 3,
wherein the activation element is Ce.

5. The phosphor according to claim 1,
wherein the second phase comprises a fluorescence exhibiting phase.

6. The phosphor according to claim 1,
wherein the second phase comprises a Ce:YAG phase.

7. The phosphor according to claim 1,
wherein the first phase comprises an Al₂O₃ phase.

8. The phosphor according to claim 1,
wherein the phosphor is produced by a micro pull-down method.

9. A light source device comprising:
the phosphor according to claim 1.

10. A light source device, comprising:
the phosphor according to claim 1; and
a blue light-emitting diode and/or a blue semiconductor laser.
